(19) United States
(12) Patent Application Publication
(10) Pub. No.: US 2026/0231347 A1
(43) Pub. Date: Aug. 6, 2026

(54) MOUNTING SYSTEM WITH TRACK-TRAVELING DISCS FOR MOUNTING INFORMATION PROCESSING DEVICE TO A TWO-POST RACK

(71) Applicant: HEWLETT PACKARD ENTERPRISE DEVELOPMENT LP, Spring, TX (US)

(72) Inventors: Peng Chianghsieh, Taipei (TW); Yu-Shun Chang, Taipei (TW); Patrick Chen, Burnaby (CA)

(21) Appl. No.: 19/044,801

(22) Filed: Feb. 4, 2025

(51) Int. Cl. H05K 7/14

(52) U.S. Cl. CPC H05K 7/1489

(57) ABSTRACT

Discs for mounting an information processing device to a rail kit of a two-post rack are disclosed. The information processing includes a chassis, spools, and discs. The chassis includes a first peripheral side and a second peripheral side, each extends parallel to one another along a longitudinal axis of the chassis. The spools extend perpendicularly from each of the first and second peripheral sides in a mutually opposite direction along a lateral axis of the chassis. The discs (track-travelling discs) include at least one disc mounted to one spool on the first peripheral side of the chassis and at least another disc mounted to another spool on the second peripheral side of the chassis. Further, each disc is configured to engage with and travel along a track of a mounting rail installed in the two-post rack such that the information processing device is detachably mounted to the rack.

### BACKGROUND

Information processing devices such as a computer, a networking device, or the like may be mounted to or installed in a rack of a datacenter environment. The rack may be a mechanical structure for housing multiple information processing devices. Many racks consist of four posts or columns, referred to a four-post rack, while other racks consist of just two posts, referred to as two-post racks. The posts have mounting holes or apertures at predetermined positions to allow for attachment of the devices to the rack. In some cases, devices may be mounted directly to the posts, but more often rail kits are used to mount the devices to the rack. The rail kit is attached to the posts of the rack, and then the information processing device is mounted to the rail kit, thus allowing the information processing device to be mounted to or installed in the rack. Often, the rail kit may further allow the information processing device to be slid in and out of the rack, in some cases while remaining mounted to the rack, thus providing access to a user for a portion of the information processing device. For example, some rail kits comprise a fixed rail which is mounted to the posts and a telescoping arm which slides relative to the fixed portion, and the information processing device may be attached to the telescoping arm to facilitate sliding the device out of the rack while still remaining attached thereto.

### BRIEF DESCRIPTION OF THE DRAWINGS

Various examples will be described below with reference to the following figures.

FIG. 1 includes a schematic top view of a system having a rack, a rail kit, and an information processing device according to an example of the present disclosure.

FIG. 2 includes a perspective view of a post of a two-post rack according to an example of the present disclosure.

FIG. 3A includes a perspective view of a mounting rail of a rail kit according to an example of the present disclosure.

FIG. 3B includes a perspective view of a retention bracket of a rail kit according to an example of the present disclosure.

FIG. 3C includes a perspective view of a track-travelling disc of a rail kit or an information processing device according to an example of the present disclosure.

FIG. 3D includes a perspective view of a cantilever spring latch of a rail kit or an information processing device according to an example of the present disclosure.

FIG. 4 includes a perspective view of an information processing device according to an example of the present disclosure.

FIG. 5A includes a perspective view of a wider hole portion of the track-travelling disc of FIG. 3C engaged to a spool of the information processing device of FIG. 4 and the cantilever spring latch of FIG. 3D in an unlatched state according to an example of the present disclosure.

FIG. 5B includes a perspective view of a narrower portion of the track-travelling disc of FIG. 3C engaged to a spool of the information processing device of FIG. 4 and the cantilever spring latch of FIG. 3D in a latched state according to an example of the present disclosure.

FIG. 6A includes a perspective view of a rail kit having the plurality of mounting rails of FIG. 3A coupled to the plurality of retention brackets of FIG. 3B according to an example of the present disclosure.

FIG. 6B includes a perspective view of the rail kit of FIG. 6A installed in the two-post rack of FIG. 2 according to an example of the present disclosure.

FIG. 6C includes a side view of a portion of FIG. 6B according to an example of the present disclosure.

FIG. 7A includes a perspective view of an information processing device of FIG. 4 sliding in the two-post rack through the rail kit of FIG. 6A according to an example of the present disclosure.

FIG. 7B includes a cross-sectional view of the information processing device and the rail kit taken along line 7B-7B′ in FIG. 7A according to an example of the present disclosure.

FIG. 7C includes a perspective view of the information processing device installed in the two-post rack through the rail kit of FIG. 7A according to an example of the present disclosure.

FIG. 8A includes a perspective view of an information processing device according to another example of the present disclosure.

FIG. 8B includes a cross-sectional view of the information processing device taken along line 8B-8B′ in FIG. 8A according to an example of the present disclosure.

FIG. 8C includes a perspective view of the information processing device of FIG. 8A installed in a two-post rack through a rail kit of FIG. 6A according to an example of the present disclosure.

### DETAILED DESCRIPTION

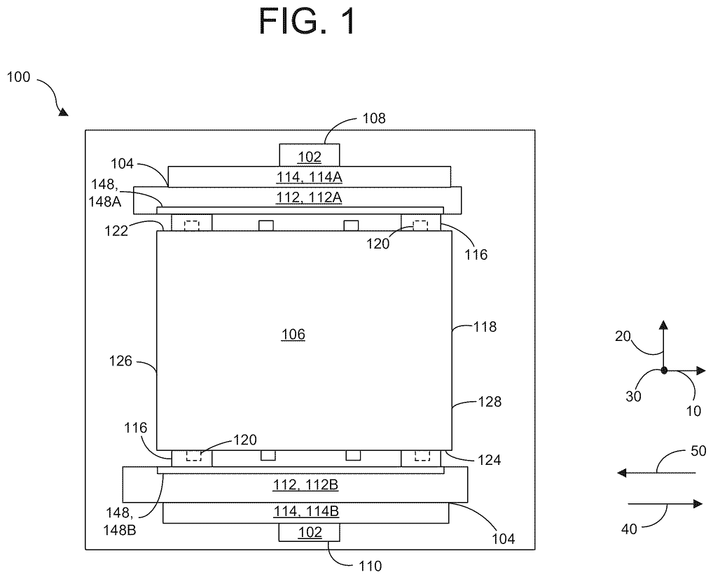

The following detailed description refers to the accompanying drawings. For purposes of explanation, certain examples are described with reference to the components illustrated in FIGS. 1-8. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the examples disclosed may be defined by the appended claims.

Rails kits are often designed to work with particular information processing devices and a particular type of rack. Thus, in some cases, an information processing device that is designed to work with one rail kit may be incompatible with another rail kit. This may be because the information processing device lacks attachment features needed for that particular rail kit, or vice versa, or it may be because the dimensions of the information processing device and rail kit are incompatible, resulting in interferences. In particular, some information processing devices which were originally designed to be used with certain four-post rack rail kits may not be compatible with existing rail kits for two post racks.

In some cases, customized two-post rail kits could be designed which would be compatible with the aforementioned information processing devices. But in many cases, these customized rail kits would be unique to a particular model, and a different rail kit may be needed for other models, due to them potentially having different dimensions or other differences. Therefore, each information processing device may require different types of customized rail kits. Furthermore, when different types of customized rail kits are made available, customers may need to order different types of rail kits which suit their requirements, and this may be cumbersome and difficult to manage. In addition, multiple numbers of different types of rail kits may need to be produced, and this may result in additional SKUs being needed and different inventory to be maintained by the manufacturers, which can in turn increase costs. Furthermore, replacing the rail kits with a new type of rail kits may be cumbersome, time consuming, expensive, and depend on the availability of inventory of such new rail kits.

A technical solution to the aforementioned problems may include providing a two-post rail kit comprising a pair of rails and a set of track-travelling discs. The discs may be mounted to existing spools on the outside of a chassis of the information processing device and may be engaged with and travel along tracks of the rails so as to detachably mount the device to the two-post rack. The discs may travel along the tracks by a sliding motion, a rolling motion (i.e., the disc rotating around the spool to which the disc is mounted), or a combination of the two.

The spools on the chassis to which the discs are mounted may be mounting features which are found in a variety of existing devices. More specifically, in some cases, the spools are designed to facilitate attachment of the devices to a four-post rail kit. For example, the spools may be arranged to attach the chassis to a telescoping arm of the rail kit. In some cases, multiple different models of devices may have these spools, which may be arranged in various locations on their respective chassis. The discs can be mounted to these spools regardless of the variation in their locations on the chassis, thus enabling the mounting systems disclosed herein to be compatible with a wide variety of systems. Thus, the need to design custom rail kits for each system can be avoided. Moreover, some of the systems may have been originally designed for use with four-post rail kits, but the mounting systems disclosed herein may nevertheless allow for these systems to be installed in a two-post rack.

In some examples, at least one disc may be mounted to one spool disposed on a first peripheral side of a chassis and at least one disc may be mounted to one spool disposed on the second peripheral side of the chassis. In such examples, each disc may engage with and travel along tracks of rail kit installed in the two-post rack to detachably mount the device to the two-post rack. In some examples, each disc may be secured to a corresponding spool using a cantilever spring latch attached to the disc. Furthermore, the rail kit may have a complimentary ear latch which may engage with an ear latch of the chassis to secure the information processing mounted on the two-post rack, to the rail kit.

In some examples, the rail kit may have a plurality of retention brackets which are attached to the mounting rails—in some examples, two retention brackets per rail. The retention brackets are configured to attach to a corresponding post of the two-post rack, thereby mounting the rail kit to the two-post rack. In such examples, at least one of the retention brackets is configured to move along the corresponding mounting rail to reposition the retention bracket at a plurality of different mounting locations along the corresponding mounting rail. This allows the distance between the two retention brackets to be changed so as to accommodate different post widths. In particular, the movable retention bracket (in some cases, all retention brackets) may include a slot which allows a fastener to be inserted therein and mate with a hole formed in the corresponding mounting rail to attach the retention bracket to the corresponding mounting rail. In such examples, the movable retention bracket may slide relative to the fastener to reposition the retention bracket along the corresponding mounting rail.

Since existing spools either as-is or with discs having mounted thereon may be used to mount the device to the four-post rack or the two-post rack, respectively, the existing spools and discs may provide flexibility, serviceability, and benefit from supply chain in terms of reducing the number of ready-made rail kits needed in the inventory. Further, the discs are inexpensive to assemble, maintain, and replace, since discs may be easily added to or removed from the existing spools to make the information processing device compatible to be mounted to either two-post rack or four-post rack. Since the rail kits may be expanded or contracted based on a width of the post of the two-post rack so as to make it compatible for attaching to the post, the rail kit further provides flexibility, serviceability, and benefit from supply chain in terms of reducing the number of ready-made rail kits needed in the inventory. Additionally, the latching features of the rail kit may allow the information processing device mounted to the two-post rack to be secured.

As used herein, an “information processing device” may be a storage array, storage device, storage enclosure, server, blade server, desktop or laptop computer, computer cluster, node, partition, or any other device or equipment including a controller, a processing resource, or the like. As used herein, “rack unit” or “U” may refer to the unit of measurement to define the height of a rack frame and the height of the equipment in a rack frame (such as, information processing devices). Each rack unit may be equivalent to 44.50 millimeters or 1.75 inches. For example, an information processing device, such as a rack server, may have a height of 1 U or 1 rack unit (in other words, 44.55 millimeters or 1.75 inches) or 2 U or 2 rack units (in other words, 89 millimeters or 3.5 inches).

In the description hereinafter, an example system and/or a rack and/or a rail kit and/or an information processing device are described with the help of several views oriented per a first axis 10 extending along a horizontal direction, a second axis 20 extending along a lateral direction, and a third axis 30 extending along a vertical direction, which are marked in the respective Figures. Further, the vertical, horizontal axial, and lateral directions may be perpendicular to each other and the measurements along the vertical, horizontal, and lateral directions may be referred to as a height, a width, and a length, respectively. The axes 10, 20, and 30 and directions or positional relationships described herein in relation to these axes are fixed relative to the devices as shown in the figures and not to any external reference frame (such as the ground), and direction terms used herein should be understood in relation to these axes and not to any external reference frame. For example, horizontal and vertical, as used herein, do not refer to orientations relative to the ground.

Referring to the Figures, FIG. 1 depicts a schematic top view of a system 100 including a rack 102, a rail kit 104, and an information processing device 106. It should be understood that FIG. 1 is not intended to illustrate specific shapes, dimensions, or other structural details accurately or to scale, and that implementations of the system 100 and such system 100 may have different numbers and arrangements of the illustrated components and may also include other parts that are not illustrated. The system 100 may be configured to host multiple information processing devices 106 and associated components therein.

The rack 102 may be a standardized post designed to house multiple information processing devices 106 which are mounted to the rack 102 either directly or via a mounting system (such as the rail kit 104). In some examples, the rack is a two-post rack. In such examples, the rack 102 includes a first post 108 and a second post 110 which are disposed spaced apart from each other along a lateral axis 20 and positioned parallel to one another. Further, each of the first and second posts 108, 110 extends along a radial direction 30 and may be configured to attach with a base (not labeled) of the system 100. Each of the first and second posts 108, 110 may be further configured to have multiple information processing devices mounted thereto, either directly or via mounting systems (like rail kits), with the devices or mounting systems being vertically spaced apart from each other along the radial direction 30. In particular, each of the first and second posts 108, 110 may include mounting features (e.g., apertures) distributed along the radial direction 30 at predetermined positions, with these mounting features being arranged to engage with corresponding mounting features of the devices/mounting systems to secure them to the posts 108, 110.

The rail kit 104 may be a framework configured to mount the information processing device 106 to the rack 102. The rail kit 104 may include two mounting rails 112, a plurality of retention brackets 114, and a plurality of track-travelling discs 116 (or a plurality of discs 116).

Each mounting rail 112 may be configured to allow mounting of the information processing device 106 to the rack 102. For example, each mounting rail 112 may have a track 148 extending along a first side (not labeled) of the mounting rail 112, which may allow the plurality of discs 116 attached to the information processing device 106 to slide or roll along the track and mount the information processing device 106 to the rack 102. The track 148 may be formed from a portion of the mounting rail 112 which has a generally C-shaped cross-section, forming a top channel, a bottom channel, and a track wall connecting the two together. Each of these channels extends lengthwise along the mounting rail 112, with the bottom channel being located along a bottom side of the mounting rail 112, the top channel being located along a top side of the mounting rail 112. Moreover, each of the channels has a U-shaped cross-section, with an open end of the U facing upward in the bottom channel, and downward in the top channel. In the example of FIG. 1, each rail kit 104 includes a first mounting rail 112A having one track 148A and a second mounting rail 112B having another track 148B, which may be configured to mount the information processing device 106 to the rack 102.

Each retention bracket 114 may be configured to mount a corresponding mounting rail 112 to the rack 102. The retention brackets 114 include a first retention bracket 114A and a second retention bracket 114B. In such examples, each of the first and second retention brackets 114A, 114B, respectively, may be configured to attach one mounting rail of the plurality of mounting rails 112 to a corresponding rack 102. In particular, the first retention bracket 114A is attached to a second side (not labeled) of the first mounting rail 112A. Later, the first retention bracket 114A is further attached to the first post 108. Similarly, the second retention bracket 114B is attached to a second side (not labeled) of the second mounting rail 112B. Later, the second retention bracket 114B is further attached to the second post 110. Thus, the retention brackets 114 may attach the mounting rails 112 to the rack 102 and configure such attached mounting rails 112 to mount the information processing device 106 to the rack 102 through the rail kit 104.

Each disc 116 may be configured to engage with and travel along the track of the mounting rail of the plurality of mounting rails 112 to mount the information processing device 106 to the rack 102. For example, each disc 116 may be first mounted to a corresponding spool 120 of the information processing device 106 such that each disc 116 may rotate or slide relative to the corresponding spool 120. Later, each disc 116 may be positioned in the track and configured to travel along the track by at least one of a sliding motion or a rolling motion relative to the corresponding spool 120 so as to mount the information processing device 106 to the rack 102. The discs 116 may be engaged with the tracks by inserting a top edge of the disc into the top channel of the track and the bottom edge of the disc into the bottom channel of the track.

The information processing device 106 such as a server includes a chassis 118, a plurality of spools 120, and a plurality of discs 116. As discussed herein, in some examples, the plurality of discs 116 may be part of the rail kit 104. In such examples, the plurality of discs 116 may be mounted to the information processing device 106. In some other examples, the plurality of discs 116 may be one of the components of the information processing device 106. In such examples, the plurality of discs 116 may be pre-mounted to or pre-installed in the information processing device 106, as discussed in detail below.

The chassis 118 may be an enclosure configured to house and provide support to electronic components (not shown) disposed within the enclosure of the information processing device 106. In some examples, the chassis 118 may be formed by a first peripheral side 122, a second peripheral side 124, a base (not shown), a cover (not shown), a rear panel 126, and a front panel 128. Each of the first peripheral side 122 and the second peripheral side 124 extends parallel to one another along a longitudinal axis 10 of the chassis 118. Further, the first and second peripheral sides 122, 124, respectively, may be connected to the base, the cover, the rear and front panels 126, 128, respectively, to define an internal volume of the chassis 118 which may be configured to house and provide support to electronic components of the information processing device 106.

The plurality of spools 120 is disposed spaced apart from one another and extends perpendicularly from each of the first and second peripheral sides 122, 124 in a mutually opposite direction along the lateral axis 20 of the chassis 118. In some examples, at least one disc 116 is mounted to one spool 120 on the first peripheral side 122 of the chassis 118 and at least one disc 116 is mounted to one spool 120 on the second peripheral side 124 of the chassis 118. In the example of FIG. 1, two discs 116 are mounted on two spools among the plurality of spools 120 extending from the first peripheral side 122 and two discs 116 are mounted on two spools among the plurality of spools 120 extending from the second peripheral side 124. The two spools 120 on which the two discs 116 are mounted may be positioned adjacent to the front and rear panels 128, 126.

In some examples, the plurality of spools 120 may be configured to directly mount the information processing device 106 to a four-post rack (not shown) through a compatible rail kit. However, the plurality of spools 120 may be incompatible to directly mount the information processing device 106 to the two-post rack of the present disclosure. Accordingly, in such examples, the plurality of discs 116 mounted to the plurality of spools 120 of the information processing device 106 may allow the information processing device 106 to be detachably mounted to the two-post rack 102 through the mounting rail 112 installed in the two-post rack 102.

In one or more examples, the information processing device 106 may be first positioned between the mounting rails 112 of the rail kit 104 such that the plurality of discs 116 disposed adjacent to the rear panel 126 is located adjacent to the first and second mounting rails 112A, 112B. Later, the plurality of discs 116 disposed adjacent to the rear panel 126 is slidably engaged in the tracks of the first and second mounting rails 112A, 112B and the information processing device 106 is pushed in a first direction 40 along the longitudinal axis 10 until the plurality of discs 116 disposed adjacent to the front panel 128 are also slidably engaged in the tracks of the first and second mounting rails 112A, 112B, thereby mounting the information processing device 106 to the rack 102. In one or more examples, the plurality of discs 116 may travel either by sliding motion or rolling motion relative to the corresponding spool 120 along the track so as to mount the information processing device 106 to the rack 102 through the rail kit 104. In some examples, the information processing device 106 may be pulled in a second direction 50 opposite to the first direction 40 along the longitudinal axis 10 to either completely unmount or partially unmount the information processing device 106 from the rack 102. In particular, the plurality of discs 116 may travel either by sliding motion or rolling motion relative to the corresponding spool 120 along the track so as to unmount the information processing device 106 from the rack 102 through the rail kit 104.

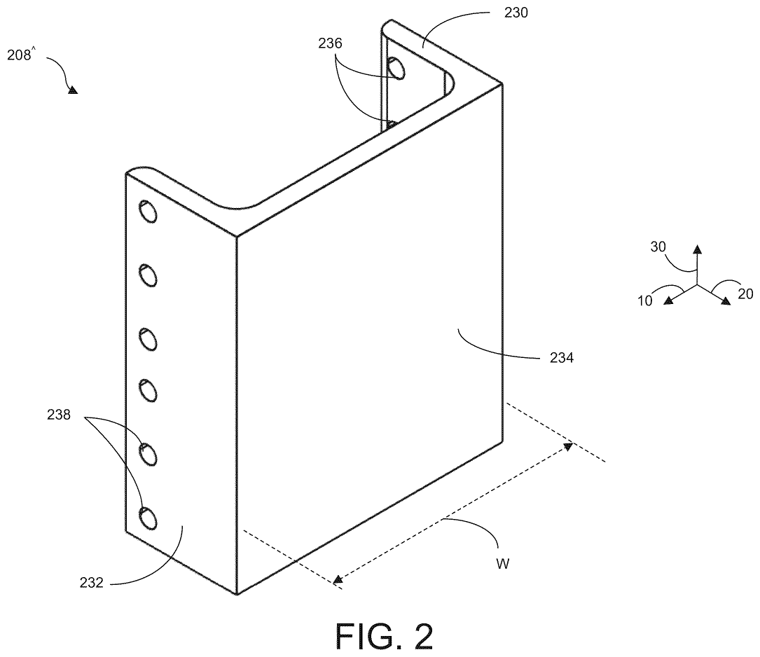

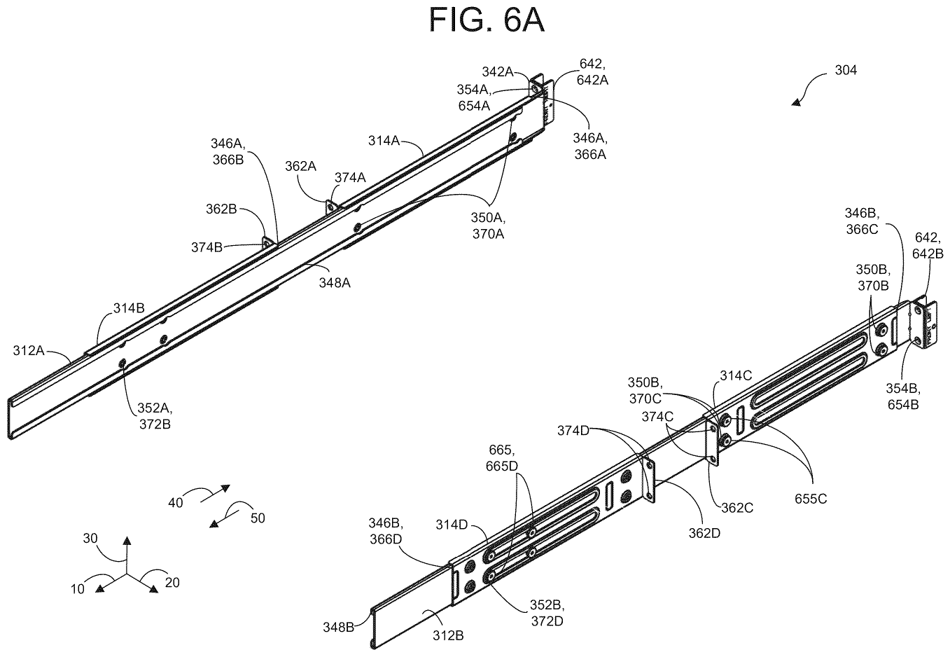

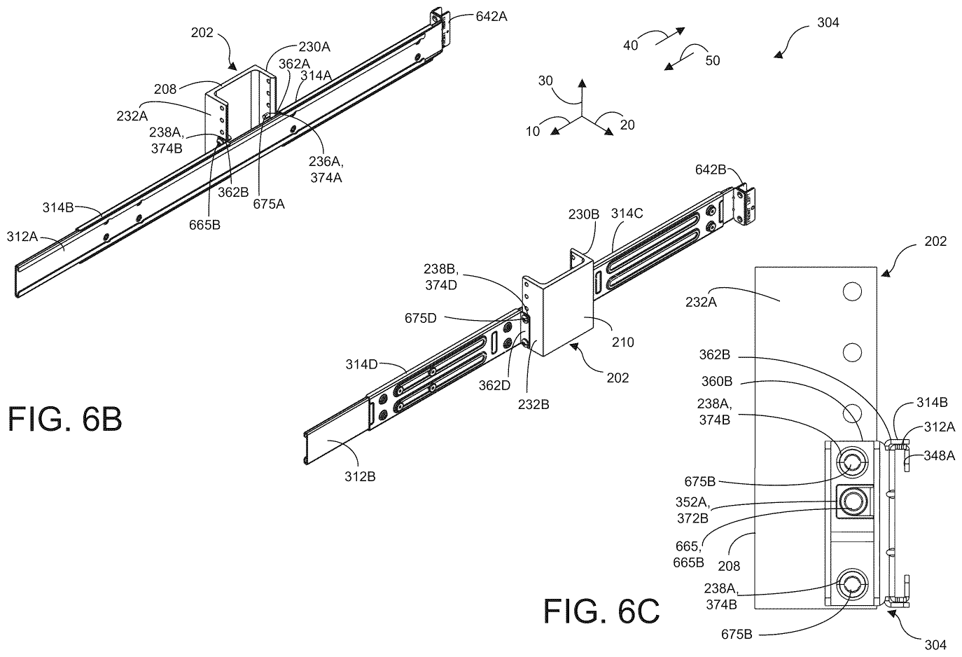

FIG. 2 depicts a perspective view of a post 208\hat{ } (e.g., one of a first post 208 or a second post 210) of a two-post rack 202 (as shown in FIG. 6B). In some examples, the post 208\hat{ } is a U-shaped column having a first side 230, a second side 232, and a body 234 connecting the first and second sides 230, 232 to each other and defining a width W of the post 208\hat{ }. In some examples, the width W may be between 3 inches to 6 inches. Each of the first and second sides 230, 232 extends perpendicularly from the body 234. The first side 230 includes a plurality of first mounting holes 236 disposed spaced apart from each other along a radial direction 30. Similarly, the second side 232 includes a plurality of second mounting holes 238 disposed spaced apart from each other along the radial direction 30. Further, each mounting hole of the plurality of first mounting holes 236 disposed on the first side 230 is aligned with a corresponding mounting hole of the plurality of second mounting holes 238 disposed on the second side 232. In one or more examples, the plurality of first mounting holes 236 and the plurality of second mounting holes 238 formed in the post 208\hat{ } (e.g., in each of the first and second posts 208, 210) may be used to mount one or more rail kits (e.g., one rail kit 304, as shown in FIGS. 6A-6C) to the two-post rack 202. In other words, the post 208\hat{ } (e.g., the first and second posts 208, 210) may allow mounting of a rail kit 304 having one first mounting rail 312A and one second mounting rail 312B (as shown in FIGS. 6A-6C) to the two-post rack 202.

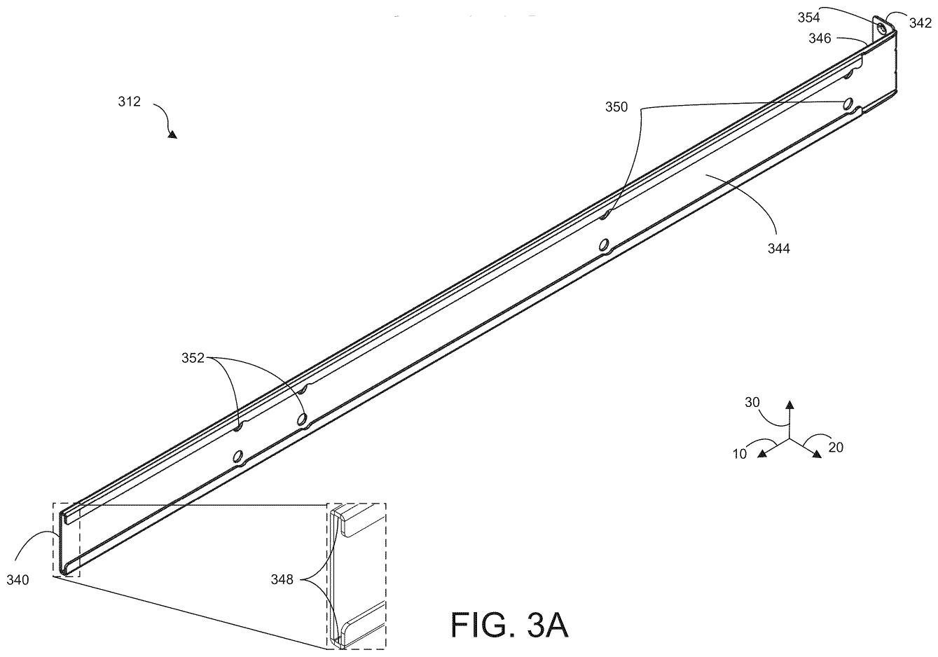

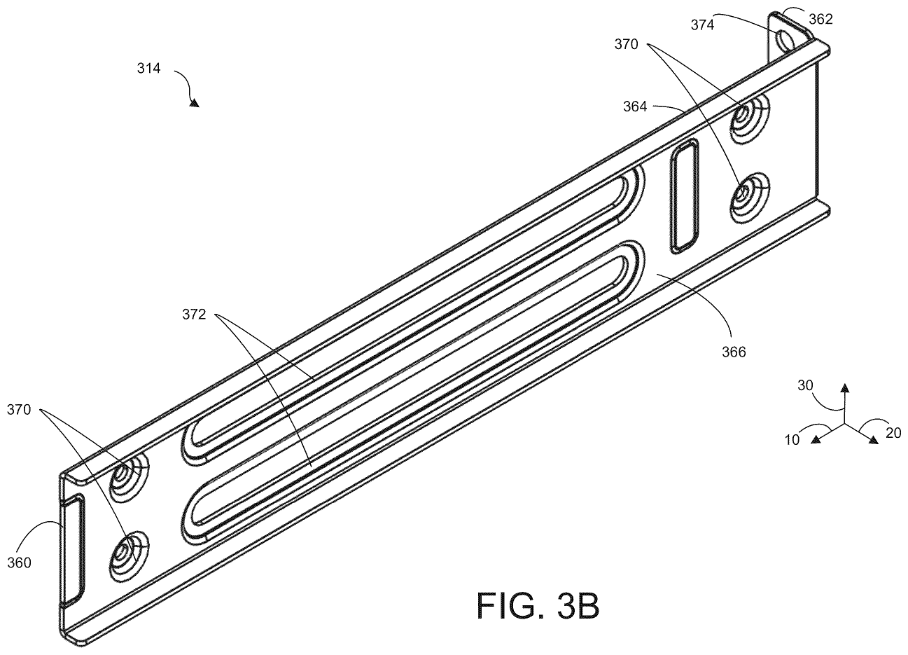

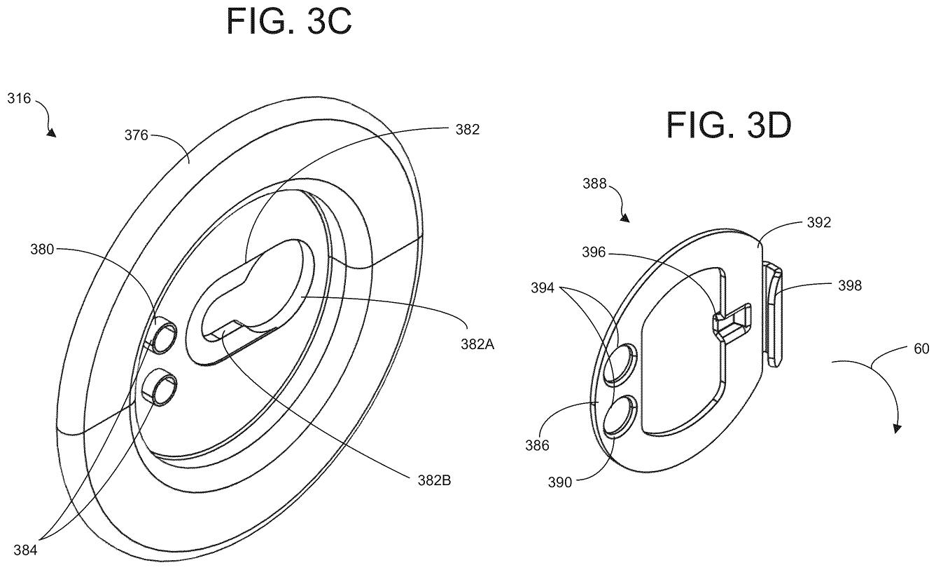

FIG. 3A depicts a perspective view of a mounting rail (e.g., one of a first mounting rail 312A or a second mounting rail 312B) of a plurality of mounting rails 312 of a rail kit 304 (as shown in FIGS. 6A-6C). In some examples, the mounting rail 312 is an L-shaped structure having an attachment member 340 and a body 342 extending perpendicularly from one end of the attachment member 340. The mounting rail 312 includes a first side 344, a second side 346 opposite to the first side 344, and a track 348 extending along the first side 344. In some examples, the track 348 has a C-shaped pathway extending along the first side 344. The attachment member 340 of the mounting rail 312 further includes a first set of attachment holes 350 and a second set of attachment holes 352. In some examples, the first set of attachment holes 350 is disposed adjacent to the body 342 and the second set of attachment holes 352 is disposed adjacent to another end of the attachment member 340. In one or more examples, the first set and second set of attachment holes 350, 352 may be used to attach the mounting rail 312 to a plurality of retention brackets 314 (e.g., a first retention bracket 314A and a second retention bracket 314B, as shown in FIG. 6A, or a third retention bracket 314C and a fourth retention bracket 314D, as shown in FIG. 6A). The body 342 of the mounting rail 312 further includes a plurality of ear mounting holes 354. In some examples, the plurality of ear mounting holes 354 is disposed spaced apart from each other along the radial direction 30. Further, the plurality of ear mounting holes 354 may be used to attach the mounting rail 312 to a complementary ear latch 642 of a rail kit 304 (as shown in FIGS. 6A-6C).

FIG. 3B depicts a perspective view of a retention bracket (e.g., one of a first retention bracket 314A or a second retention bracket 314B or a third retention bracket 314C or a fourth retention bracket 314D) of a plurality of retention brackets 314 of a rail kit 304, as shown in FIG. 6A. In some examples, the retention bracket 314 is an L-shaped structure having an attachment member 360 and a body 362 extending perpendicularly from one end of the attachment member 360. The retention bracket 314 includes a first side 364 and a second side 366 opposite to the first side 364. In some examples, the second side 366 of the attachment member 360 has a U-shaped structure which may be configured to engage with a second side 346 of the mounting rail 312. Further, the attachment member 360 of the retention bracket 314 includes a set of attachment holes 370 and a set of slots 372. In some examples, the set of slots 372 is disposed spaced apart from each other along the radial direction 30 and disposed between the set of attachment holes 370. In one or more examples, the set of attachment holes 370 or the set of slots 372 may be used to attach the retention bracket 314 to the mounting rail 312. For example, the set of attachment holes 370 may be aligned with the first set of attachment holes 350 (as shown in FIG. 3A), when the second side 346 of the mounting rail 312 is slidably mounted to the second side 366 of the retention bracket 314. In such examples, the first set of attachment holes 350 and the set of attachment holes 370 may be used together to rigidly attach the retention bracket 314 to a portion of the mounting rail 312. In some other examples, the set of slots 372 may be aligned with the second set of attachment holes 352 (as shown in FIG. 3A), when the second side 346 of the mounting rail 312 is slidably mounted to the second side 366 of the retention bracket 314. In such examples, the second set of attachment holes 352 and the set of slots 372 may be used together to movably attach the retention bracket 314 to another portion of the mounting rail 312. In other words, when the set of slots 372 in the retention bracket 314 is used to attach to the second set of attachment holes 352 in the mounting rail 312, the retention bracket 314 may be movable along the mounting rail 312 to reposition at a plurality of different mounting locations along the mounting rail 312 based on the width W of the posts 208, 210.

The body 362 of the retention bracket 314 includes a plurality of third mounting holes 374 which are disposed spaced apart from each other along the radial direction 30. Further, each mounting hole of the plurality of third mounting holes 374 is vertically aligned with a corresponding mounting hole of one of a plurality of first mounting holes 236 or a plurality of second mounting holes 238 of the post 208\hat{ }. In such examples, the plurality of third mounting holes 374 and the mounting holes of one of the first mounting holes 236 or the plurality of second mounting holes 238 may be used to attach the retention bracket 314 to the post 208\hat{ } and thereby mounting the mounting rail 312 to the two-post rack 202 via the retention bracket 314. In other words, the retention bracket 314 may mount a portion of the mounting rail 312 to the two-post rack 202 and/or the other portion of the mounting rail 312 to the two-post rack 202.

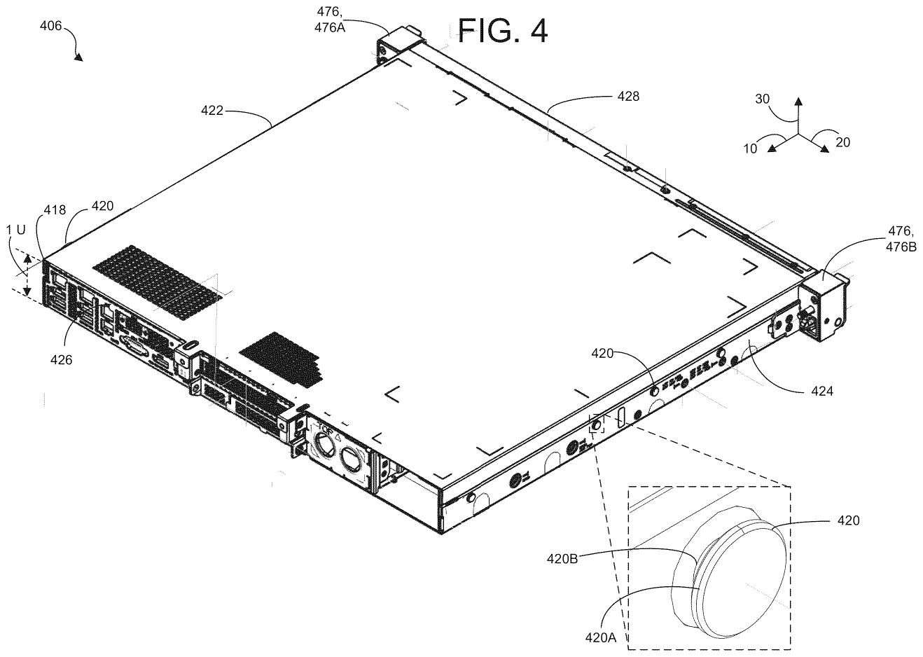

FIG. 3C depicts a perspective view of a track-travelling disc (or a disc 316). In some examples, the disc 316 may be part of a rail kit 304 (as shown in FIGS. 6A-6C) or an information processing device 406 (as shown in FIG. 4). The disc 316 includes a circular member 376 positioned at a circumference of the disc 316, and an attachment member 380 and a keyhole 382 at a center of the disc 316. The attachment member 380 includes two protrusions 384 disposed spaced apart from each other. In some examples, the attachment member 380 may be configured to be coupled with a cantilever spring latch 388 (as shown in FIG. 3D) to lock the disc 316 to the information processing device 406. The keyhole 382 has a wider hole portion 382A and a narrower hole portion 382B extending from the wider hole portion 382A. In some examples, the keyhole 382 may be configured to be engaged with a spool 420 of the information processing device 406 to mount the disc 316 to the spool 420. Further, the disc 316 mounted to the spool 420 may be configured to detachably mount the information processing device 406 to the mounting rail 312 installed in the two-post rack 202. In other words, the disc 316 is configured to engage with and travel along a track 348 of the mounting rail 312 such that the information processing device 406 is detachably mounted to the two-post rack 202.

FIG. 3D depicts a perspective view of a cantilever spring latch 388. In some examples, the cantilever spring latch 388 is used to secure or release the disc 316 from the spool 420. The cantilever spring latch 388 includes a fixed end 386 having a complementary attachment member 390 and a free end 392 having a locking tab 396 and a handle 398. In some examples, the complementary attachment member 390 includes two holes 394 disposed spaced apart from each other. The fixed end 386 of the cantilever spring latch 388 may be coupled to the disc 316 (as shown in FIG. 3C) by engaging the attachment and complementary attachment members 380, 390 (e.g., two protrusions 384 and two holes 394) to one another such that the free end 392 of the cantilever spring latch 388 is movable (e.g., rotatable along axis 60) between a latched state and an unlatched state to releasably secure the disc 316 to the spool 420. In some examples, in the unlatched state, the locking tab 396 may be configured to be disengaged from the wider hole portion 382A of the keyhole 382 to allow the disc 316 to be released from the spool 420. Similarly, in the latched state, the locking tab 396 may be configured to be engaged with the wider hole portion 382A of the keyhole 382 to prevent the disc 316 to be released from the spool 420 or secure the disc 316 to the spool 420.

FIG. 4 depicts a perspective view of an information processing device 406. In some examples, the information processing device 406 is a server. In the example of FIG. 4, the information processing device 406 may have a height of 1 U or 1 rack unit (in other words, 44.55 millimeters or 1.75 inches). The information processing device 406 includes a chassis 418, a plurality of spools 420, a plurality of discs 316, and a plurality of ear latches 476. As discussed herein, in some examples, the plurality of discs 316 (as shown in FIG. 3C) may be part of a rail kit 304 (as shown in FIGS. 6A-6C). In such examples, the plurality of discs 316 may be mounted to the information processing device 406. In some other examples, the plurality of discs 316 may be part of the information processing device 406. In such examples, the plurality of discs 316 may be pre-mounted to or pre-installed in the information processing device 406, as discussed in detail below.

The chassis 418 may be formed by a first peripheral side 422, a second peripheral side 424, a base (not shown), a cover (not shown), a rear panel 426, and a front panel 428. Each of the first peripheral side 422 and the second peripheral side 424 extends parallel to one another along a longitudinal axis 10 of the chassis 418. Further, the first and second peripheral sides 422, 424, respectively, may be connected to the base, the cover, the rear and front panels 426, 428, respectively, to define an internal volume of the chassis 418 which may be configured to house and provide support to electronic components of the information processing device 406.

The plurality of spools 420 is disposed spaced apart from one another and extends perpendicularly from each of the first and second peripheral sides 422, 424 in a mutually opposite direction along the lateral axis 20 of the chassis 418. Each spool includes a wider head portion 420A and a narrower shaft portion 420B extending from the wider head portion 420A. In some examples, the plurality of spools 420 may be configured to directly mount the information processing device 106 to a four-post rack (not shown) through a compatible rail kit. However, the plurality of spools 420 may be incompatible to directly mount the information processing device 406 to the two-post rack of the present disclosure.

The plurality of ear latches 476 may be positioned adjacent to the front panel 428 and coupled to one end portion of the first peripheral side 422 and the second peripheral side 424. Each of the plurality of ear latches 476 may be configured to releasably couple the chassis 418 to the rail kit 304.

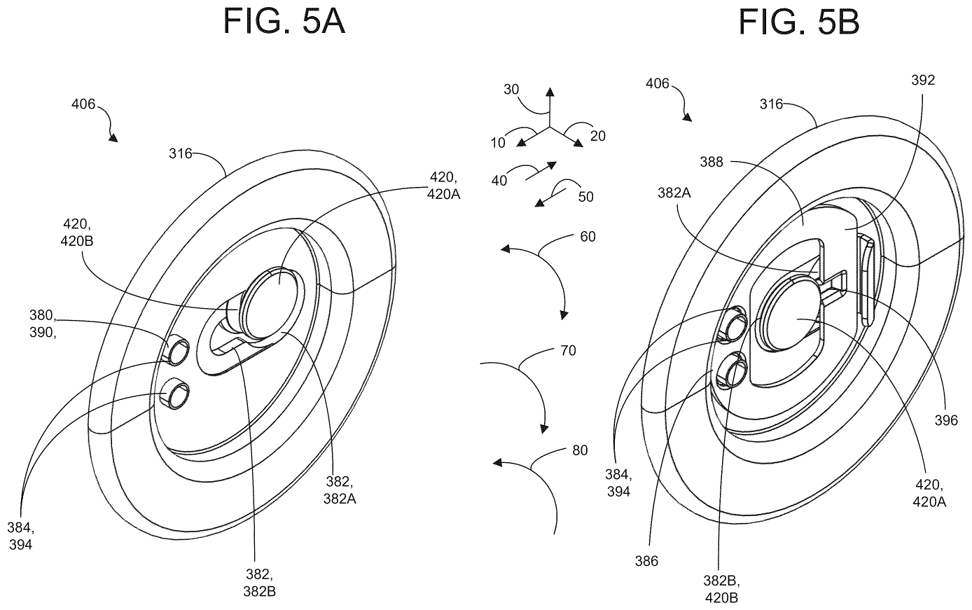

FIG. 5A depicts a perspective view of a disc 316 of FIG. 3C engaged to a spool 420 of the information processing device 406 of FIG. 4 and the cantilever spring latch 388 of FIG. 3D in an unlatched state. FIG. 5B depicts a perspective view of the disc 316 of FIG. 3C engaged to the spool 420 of the information processing device of FIG. 4 and the cantilever spring latch 388 of FIG. 3D in a latched state. In the description hereinafter, FIGS. 5A-5B are described concurrently for ease of illustration. It may be noted herein that the cantilever spring latch 388 is not shown in FIG. 5A for ease of illustration of other components in the spool 420 and the disc 316, and such non-illustration of the cantilever spring latch 388 in FIG. 5A should not be construed as a limitation of the present disclosure.

The cantilever spring latch 388 may be first mounted on the disc 316 such that the fixed end 386 of the cantilever spring latch is positioned adjacent to the attachment member 380 of the disc 316 and the free end 392 of the cantilever spring latch 388 is positioned adjacent to the keyhole 382 of the disc 316. Later, the fixed end 386 of the cantilever spring latch 388 may be coupled to the disc 316 by engaging the attachment and complementary attachment members 380, 390 (e.g., two protrusions 384 and two holes 394) to one another such that the free end 392 of the cantilever spring latch 388 is movable (e.g., rotatable along axis 60) between the latched state and the unlatched state to releasably secure the disc 316 to the spool 420.

In some examples, the cantilever spring latch 388 may be first rotated in a third direction 70 along the axis 60 to move the cantilever spring latch 388 from the latched state to the unlatched state. In the unlatched state of the cantilever spring latch 388, the disc 316 is mounted to one spool of the plurality of spools 420 such that the wider head portion 420A of the spool 420 is engaged with the wider hole portion 382A of the keyhole 382 in the disc 316 and mounting the disc 316 to the spool 420. It may be noted herein that in the unlatched state of the cantilever spring latch 388, the locking tab 396 may have moved away from the wider hole portion 382A of the keyhole 382, thereby not obstructing the insertion of wider hole portion 382A of the keyhole 382 into the spool 420. Further, the disc 316 mounted to the spool 420 is either rotatable or slidable relative to the spool 420.

Further, the disc 316 is moved in the second direction 50 along the longitudinal axis 10 such that the narrower shaft portion 420B of the spool 420 is engaged with the narrower hole portion 384B of the keyhole 382 in the disc 316, and the wider head portion 420A of the spool 420 is positioned over the narrower hole portion 384B. The cantilever spring latch 388 is later released to rotate back in a fourth direction 80 along the axis 60 and move the cantilever spring latch 388 from the unlatched state to the latched state. In the latched state of the cantilever spring latch 388, the locking tab 396 of the cantilever spring latch 388 may engage with the wider hole portion 382A of the keyhole 382 in the disc 316, thereby obstructing the disc 316 to move back in the first direction 40 along the longitudinal axis 10 and preventing the wider head portion 420A of the spool 420 to engage with the wider hole portion 382A of the keyhole 382 and securing the disc 316 to the spool 420.

Accordingly, in other words, in the unlatched state of each cantilever spring latch 388, the locking tab 396 of the cantilever spring latch 388 is disengaged from the wider hole portion 382A of the corresponding disc 316 and the wider head portion 420A of each spool 420 is positioned in the wider hole portion 382A of the corresponding disc 316 so as to release the corresponding disc 316 from the spool 420. Similarly, in the latched state of each cantilever spring latch 388, the locking tab 396 of the cantilever spring latch 388 is engaged with the wider hole portion 382A of the corresponding disc 316 and the narrower shaft portion 420B of each spool 420 is positioned in the narrower hole portion 382B of the corresponding disc 316 so as to hold the corresponding disc 316 to the spool 420.

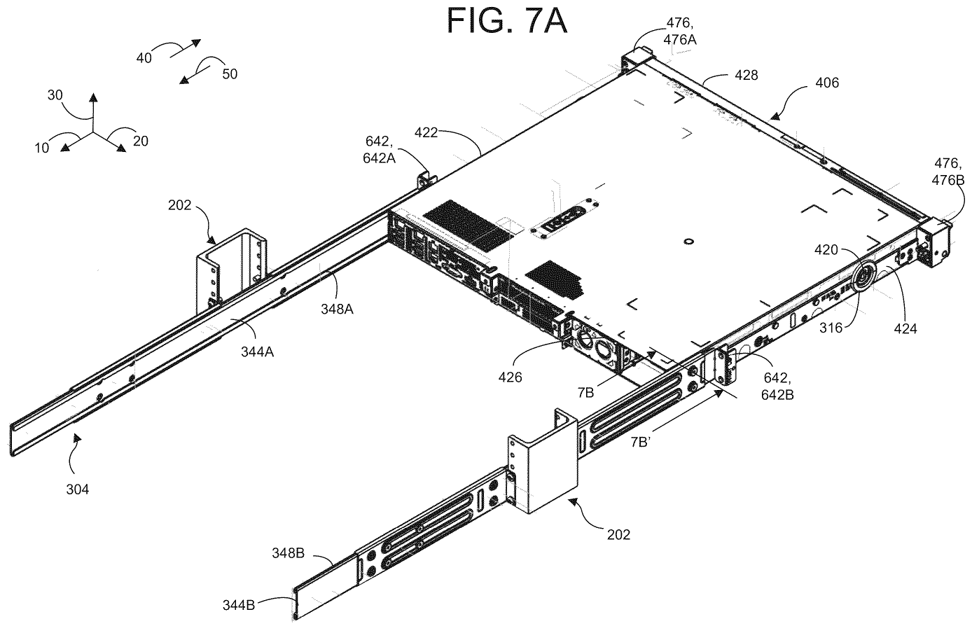

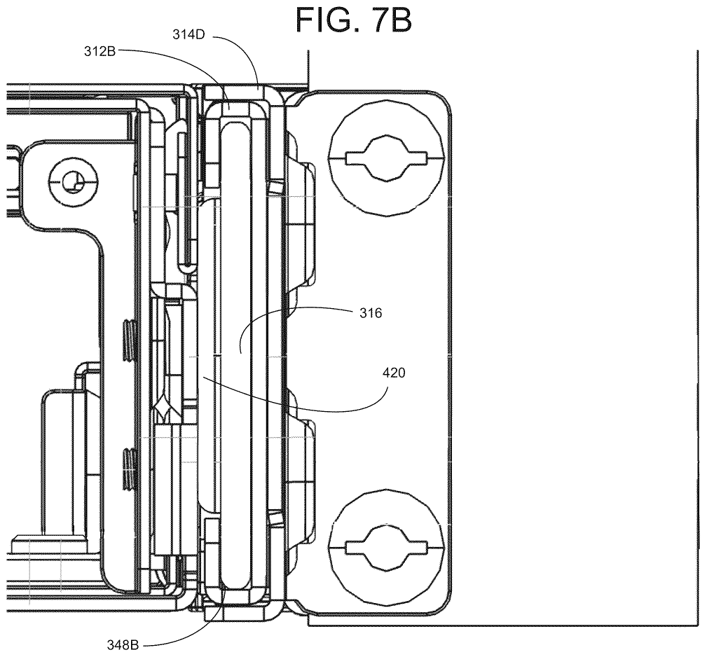

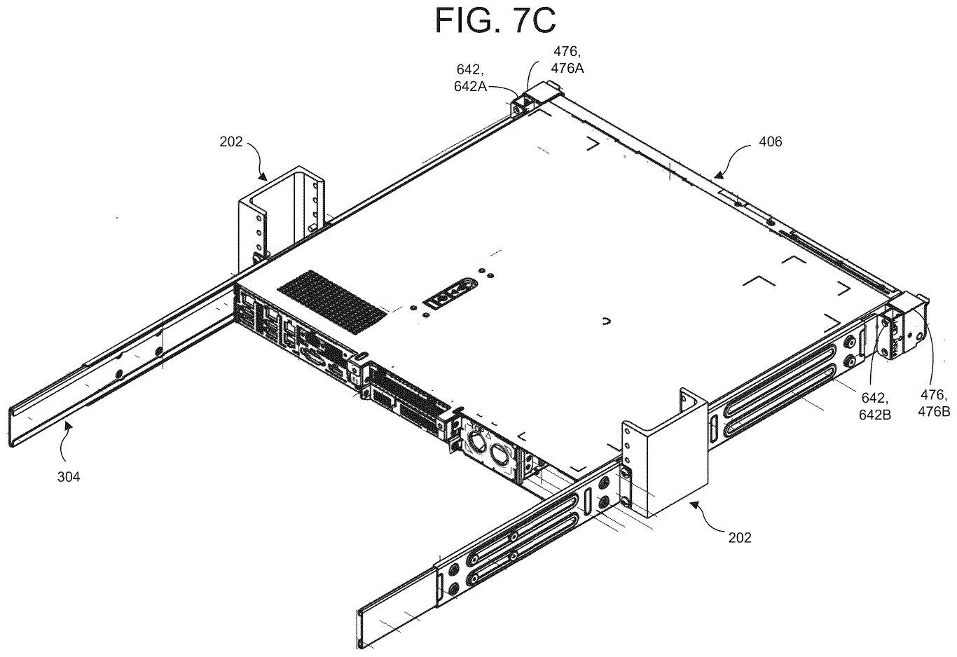

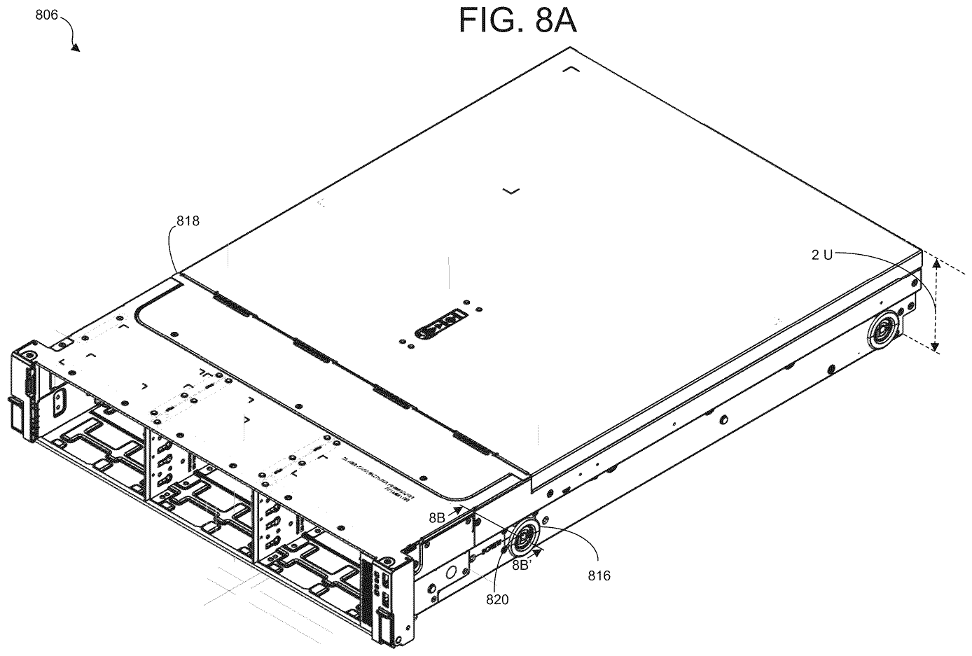

Even though not illustrated, at least one disc 316 is mounted to one spool 420 on the first peripheral side 422 of the chassis 418 (see, FIG. 4) and at least one disc 316 is mounted to one spool 420 on the second peripheral side 424 of the chassis 418, as discussed herein. In the example of FIG. 7A, the information processing device 406 may have two discs 3160 mounted to each of the first and second peripheral sides 422, 424. In such examples, one disc 316 may be positioned adjacent to the front panel 428 and another disc 316 may be positioned adjacent to the rear panel 426 on each of the first and second peripheral sides 422, 424 of the chassis 418.

FIG. 6A depicts a perspective view of a rail kit 304 having the plurality of mounting rails 312 of FIG. 3A. the plurality of retention brackets 314 of FIG. 3B, and a plurality of complementary ear latches 642. In some examples, the plurality of mounting rails 312 includes a first mounting rail 312A and a second mounting rail 312B. Similarly, the plurality of retention brackets 314 includes a first mounting bracket 314A, a second mounting bracket 314B, a third mounting bracket 314C, and a fourth mounting bracket 314D. The plurality of complementary ear latches 642 includes a first complimentary ear latch 642A and a second complimentary ear latch 642B.

The first and second mounting brackets 312A, 312B extending along a longitudinal axis 10 are disposed spaced apart from each other along a lateral direction 20. The first complimentary ear latch 642A is disposed adjacent to a body portion 342A of the first mounting bracket 312A such that a plurality of complimentary ear mounting holes 654A of the first complimentary ear latch 642A is aligned with a plurality of ear mounting holes 354A of the body portion 342A. Later, the first complimentary ear latch 642A is coupled to the body portion 342A via corresponding fasteners (not shown). Similarly, the second complimentary ear latch 642B is disposed adjacent to a body portion 342B of the second mounting bracket 312B such that a plurality of complimentary ear mounting holes 654B of the second complimentary ear latch 642B is aligned with a plurality of ear mounting holes 354B of the body portion 342B. Later, the second complimentary ear latch 642B is coupled to the body portion 342B via corresponding fasteners (not shown). In one or more examples, the plurality of complementary ear latches 642 may be used to engage with a plurality of ear latches 476 of an information processing device 406 and thereby secure the plurality of mounting rails 312 to the information processing device 406.

The first retention bracket 314A is mounted to the first mounting rail 312A such that a set of attachment holes 370A of the first retention bracket 314A is aligned with a first set of attachment holes 350A of the first mounting rail 312A. In particular, a second side 366A of the first retention bracket 314A is engaged with a second side 346A of the first mounting rail 312A, and the first retention bracket 314A is slidably moved along the first mounting rail 312A in a first direction 40 along the longitudinal axis 10 to mount the first retention bracket 314A to the first mounting rail 312A. Later, the first retention bracket 314A is fixedly attached to the first mounting rail 312A by extending a plurality of first fasteners (not shown) into corresponding attachment holes 370A of the first retention bracket 314A and corresponding first attachment holes 350A of the first mounting rail 312A.

Further, the second retention bracket 314B is mounted to the first mounting rail 312A such that a set of slots 372B of the second retention bracket 314B is aligned with a second set of attachment holes 352A of the first mounting rail 312A. In particular, a second side 366B of the second retention bracket 314B is engaged with the second side 346A of the first mounting rail 312A, and the second retention bracket 314B is slidably moved along the first mounting rail 312A in the first direction 40 along the longitudinal axis 10 to mount the second retention bracket 314B to the first mounting rail 312A. Later, the second retention bracket 314B is movably attached to the first mounting rail 312A by extending a plurality of second fasteners (not shown) into corresponding slots 372B of the second retention bracket 314B and corresponding second attachment holes 352A of the first mounting rail 312A. In other words, the second retention bracket 314B may be movable in the first and/or second direction 40, 50 along the first mounting rail 312A to reposition at a plurality of different mounting locations along the first mounting rail 312A based on the width W of the first post 208 (as shown in FIG. 6B). Since the plurality of second fasteners extends through the set of slots 372B to secure the second retention bracket 314B to the first mounting rail 312A, the set of slots 372B may allow the second retention bracket 314B to move along the first mounting rail 312A so as to reposition to a particular mounting location based on the width W of the first post 208.

Similarly, the third retention bracket 314C is mounted to the second mounting rail 312B such that a set of attachment holes 370B of the third retention bracket 314C is aligned with a first set of attachment holes 350B of the second mounting rail 312B. In particular, a second side 366C of the third retention bracket 314C is engaged with a second side 346B of the second mounting rail 312B, and the third retention bracket 314C is slidably moved along the second mounting rail 312B in a first direction 40 along the longitudinal axis 10 to mount the third retention bracket 314C to the second mounting rail 312B. Later, the third retention bracket 314C is fixedly attached to the second mounting rail 312B by extending a plurality of third fasteners 655C into corresponding attachment holes 370C of the second retention bracket 314C and corresponding first attachment holes 350B of the second mounting rail 312B.

Further, the fourth retention bracket 314D is mounted to the second mounting rail 312B such that a set of slots 372D of the fourth retention bracket 314D is aligned with a second set of attachment holes 352B of the second mounting rail 312B. In particular, a second side 366D of the fourth retention bracket 314C is engaged with the second side 346B of the second mounting rail 312B, and the fourth retention bracket 314D is slidably moved along the second mounting rail 312B in the first direction 40 along the longitudinal axis 10 to mount the fourth retention bracket 314D to the second mounting rail 312B. Later, the fourth retention bracket 314D is movably attached to the second mounting rail 312B by extending a plurality of fourth fasteners 665D into corresponding slots 372D of the fourth retention bracket 314D and corresponding second attachment holes 352B of the second mounting rail 312B. In other words, the fourth retention bracket 314D may be movable in the first and/or second direction 40, 50 along the second mounting rail 312B to reposition at a plurality of different mounting locations along the second mounting rail 312B based on the width W of the second post 210 (as shown in FIG. 6B). Since the plurality of fourth fasteners extends through the set of slots 372D to secure the fourth retention bracket 314D to the second mounting rail 312B, the set of slots 372D may allow the third retention bracket 314D to move along the second mounting rail 312B so as to reposition to a particular mounting location based on the width W of the second post 210.

In some examples, at least one retention bracket 314 is configured to be mounted to the corresponding mounting bracket 312 by inserting a fastener 665 through the slot 372 and mating the fastener 665 with a hole 352 formed in the corresponding mounting rail 312. Further, at least one retention bracket 314 is configured to slide relative to the fastener 665 to reposition the at least retention bracket 314 along the corresponding mounting rail 312.

FIG. 6B depicts a perspective view of the rail kit 304 of FIG. 6A installed in the two-post rack 202 of FIG. 2. FIG. 6C depicts a side view of a portion of FIG. 6B. In particular, FIG. 6B depicts a side view of a first post 208 of the two-post rack 202 and a first mounting rail 312A and a second retention bracket 314B of the rail kit 304. In the description hereinafter, FIGS. 6B-6C are described concurrently for ease of illustration.

The first post 208 of the two-post rack 202 is positioned between the body portions 362A, 362B of the first and second retention brackets 314A, 314B. In some examples, based on the width W of the first post 208, the second retention bracket 314B may be moved along the first mounting rail 312A to reposition to a particular mounting location. Further, the first post 208 is moved along the lateral direction 20 such that end portions of the first side 230A and the second side 232A of the first post 208 contacts the second side 346A of the first mounting rail 312A, the first set of mounting holes 236A in the first post 208 and the third set of mounting holes 374A in the first retention bracket 314A are aligned to one another, and the second set of mounting holes 238A in the first post 208 and the third set of mounting holes 374B in the second retention bracket 314C are aligned to one another. Later, the first retention bracket 314A is fixedly attached to a first side 230A of the first post 208 by extending a plurality of fifth fasteners 675A into corresponding first and third sets of mounting holes 236A, 374A in the first post 208 and the first retention bracket 314A, respectively. Similarly, the second retention bracket 314B is fixedly attached to a second side 232A of the first post 208 by extending a plurality of sixth fasteners 675B into corresponding second and third sets of mounting holes 238A, 374B in the first post 208 and the second retention bracket 314B, respectively. Thus, the first and second retention brackets 314A, 314B mount the first mounting rail 312A to the first post 208.

Similarly, the second post 210 of the two-post rack 202 is positioned between the body portions 362C, 362D of the third and fourth retention brackets 314C, 314D. In some examples, based on the width W of the second post 210, the fourth retention bracket 314D may be moved along the second mounting rail 312B to reposition to a particular mounting location. Further, the second post 210 is moved along the lateral direction 20 such that end portions of the first side 230B and the second side 232B of the first post 210 contacts the second side 346B of the second mounting rail 312B, the first set of mounting holes 236B in the second post 210 and the third set of mounting holes 374C in the third retention bracket 314C are aligned to one another, and the second set of mounting holes 238B in the second post 210 and the third set of mounting holes 374D in the fourth retention bracket 314D are aligned to one another. Later, the second retention bracket 314C is fixedly attached to a first side 230B of the second post 210 by extending a plurality of seventh fasteners 675C into corresponding first and third sets of mounting holes 236B, 374C in the second post 210 and the third retention bracket 314C, respectively. Similarly, the fourth retention bracket 314D is fixedly attached to a second side 232B of the second post 210 by extending a plurality of eight fasteners 675D into corresponding second and third sets of mounting holes 238B, 374D in the second post 210 and the fourth retention bracket 314D, respectively. Thus, the third and fourth retention brackets 314C, 314D mount the second mounting rail 312B to the second post 210.

FIG. 7A depicts a perspective view of an information processing device of FIG. 4 sliding into a two-post rack 202 through the rail kit 304 of FIG. 6A. FIG. 7B depicts a cross-sectional view of the information processing device 406 and the rail kit 304 taken along line 7B-7B′ in FIG. 7A. FIG. 7C depicts a perspective view of the information processing device 406 installed in the two-post rack 202 through the rail kit 304 of FIG. 7A. In the description hereinafter, FIGS. 7A-7C are described concurrently for ease of illustration.

The information processing device 406 may be first positioned between the mounting rails 312 of the rail kit 304 such that the plurality of discs 316 disposed adjacent to the rear panel 426 is located adjacent to the complementary ear latches 642 of the first and second mounting rails 312A, 312B. Later, the plurality of discs 316 disposed adjacent to the rear panel 426 is slidably engaged in the tracks 348A, 348B of the first and second mounting rails 312A, 312B, respectively, and the information processing device 406 is pushed in a first direction 40 along the longitudinal axis 10 until the plurality of discs 316 disposed adjacent to the front panel 428 are also slidably engaged in the tracks 348A, 348B of the first and second mounting rails 312A, 312B and the complementary ear latches and the ear latches 642, 476 are engaged to one another, thereby mounting the information processing device 406 to the two-post rack 202 and securing the rail kit 304 to the chassis 418. In one or more examples, the plurality of discs 316 may travel either by sliding motion or rolling motion relative to a narrower shaft portion 420B of the corresponding spool 420 along the track 348A, 348B so as to mount the information processing device 406 to the two-post rack 202 through the rail kit 304.

Even though not illustrated, in some examples, the information processing device 406 may be pulled in a second direction 50 opposite to the first direction 40 along the longitudinal axis 10 to either completely unmount or partially unmount the information processing device 406 from the two-post rack 202. In particular, the plurality of discs 316 may travel either by sliding motion or rolling motion relative to the corresponding spool 420 along the tracks 348A, 348B so as to unmount the information processing device 406 from the two-post rack 202 through the rail kit 304.

Accordingly, in one or more examples, In a mounted state of the plurality of track-tracking discs 316 to the plurality of spools 420 of the information processing device 406, the plurality of track-travelling discs 316 is configured to engage with and travel along the tracks 348A, 348B of the plurality of mounting rails 312 to detachably mount the information processing device 406 to the two-post rack 202.

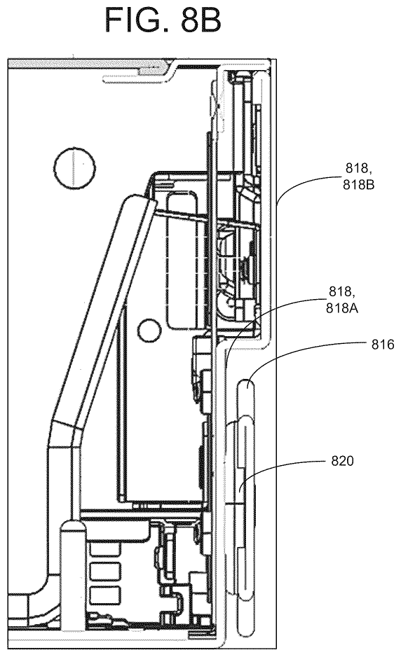

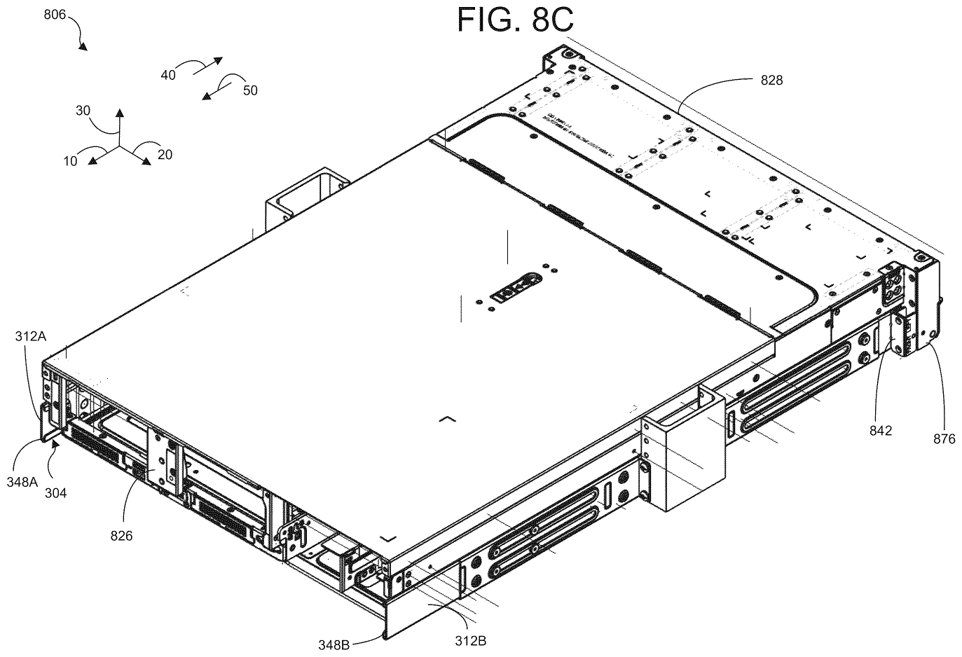

FIG. 8A depicts a perspective view of another information processing device 806. 8B depicts a cross-sectional view of the information processing device 806 taken along line 8B-8B′ in FIG. 8A. FIG. 8C depicts a perspective view of the information processing device 806 of FIG. 8A installed in a two-post rack 202 through a rail kit 304 of FIG. 6A. In the description hereinafter, FIGS. 8A-8C are described concurrently for ease of illustration.

The information processing device 806 is substantially similar to an information processing device 406 discussed hereinabove in the example of FIG. 4, expect the information processing device 806 may have a height of 2 U or 2 rack unit (in other words, 89 millimeters or 3.5 inches). Therefore, the information processing device 806 is not discussed in greater detail herein to maintain the brevity of the disclosure. The information processing device 806 includes a chassis 818, a plurality of spools 820, and a plurality of discs 816. In one or more examples, the chassis 818 has a stepped configured with a lower step 818A including the plurality of spools 820 and the upper step 818B having other electronic components therein. The plurality of discs 316 of the information processing device 806 is disposed adjacent to the rear panel 426 and is slidably engaged in the tracks 348A, 348B of the first and second mounting rails 312A, 312B, respectively, and the information processing device 806 is pushed in a first direction 40 along the longitudinal axis 10 until the plurality of discs 816 disposed adjacent to the front panel 828 are also slidably engaged in the tracks 348A, 348B of the first and second mounting rails 312A, 312B and the complementary ear latches and the ear latches 842, 876 are engaged to one another, thereby mounting the information processing device 806 to the two-post rack 202 and securing the rail kit 304 to the chassis 818. In one or more examples, the plurality of discs 816 may travel either by sliding motion or rolling motion relative to the corresponding spool 820 along the track 348A, 348B so as to mount the information processing device 806 to the two-post rack 202 through the rail kit 304.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. An information processing device comprising:
a chassis comprising a first peripheral side and a second peripheral side, each extending parallel to one another along a longitudinal axis of the chassis;
a plurality of spools extending perpendicularly from each of the first and second peripheral sides in a mutually opposite direction along a lateral axis of the chassis; and
a plurality of track-travelling discs including at least one disc mounted to one spool of the plurality of spools on the first peripheral side of the chassis and at least one disc mounted to one spool of the plurality of spools on the second peripheral side of the chassis, each disc of the plurality of track-travelling discs is configured to engage with and travel along a track of a mounting rail installed in a rack such that the information processing device is detachably mounted to the rack.

2. The information processing device of claim 1, wherein the plurality of spools arranged in the information processing device is configured to detachably mount the information processing device to the mounting rail installed in a four-post rack.

3. The information processing device of claim 1, wherein the plurality of track-travelling discs mounted to the plurality of spools is configured to detachably mount the information processing device to the mounting rail installed in a two-post rack.

4. The information processing device of claim 1, wherein each spool comprises a wider head portion and a narrower shaft portion extending from the wider head portion, and wherein each disc comprises an attachment member and a keyhole having a wider hole portion and a narrower hole portion extending from the wider hole portion.

5. The information processing device of claim 4, further comprising a plurality of cantilever spring latches, each including a fixed end having a complementary attachment member and a free end having a locking tab, wherein the fixed end of each cantilever spring latch is coupled to the corresponding disc by engaging the attachment and complementary attachment members to one another such that the free end of the cantilever spring latch is movable between a latched state and an unlatched state to releasably secure the disc to a corresponding spool.

6. The information processing device of claim 5, wherein, in the unlatched state of each cantilever spring latch, the locking tab of the cantilever spring latch is disengaged from the wider hole portion of the corresponding disc and the wider head portion of each spool is positioned in the wider hole portion of the corresponding disc so as to release the corresponding disc from the spool.

7. The information processing device of claim 5, wherein, in the latched state of each cantilever spring latch, the locking tab of the cantilever spring latch is engaged with the wider hole portion of the corresponding disc and the narrower shaft portion of each spool is positioned in the narrower hole portion of the corresponding disc so as to hold the corresponding disc to the spool.

8. The information processing device of claim 4, wherein each disc is configured to travel along the track by at least one of a sliding motion or a rolling motion relative to a narrower shaft portion of a corresponding spool.

9. A rail kit comprising:
a plurality of mounting rails, each comprising a first side, a second side opposite to the first side, and a track extending along the first side;
a plurality of retention brackets, each configured to be mounted to the second side of a corresponding mounting rail of the plurality of mounting rails and to a post of a two-post rack; and
a plurality of track-travelling discs, each configured to be mounted to a spool of a plurality of spools of an information processing device, and wherein, in a mounted state of the plurality of track-tracking discs to the plurality of spools of the information processing device, the plurality of track-travelling discs is configured to engage with and travel along the tracks of the plurality of mounting rails to detachably mount the information processing device to the two-post rack.

10. The rail kit of claim 9, wherein at least one retention bracket of the plurality of retention brackets is configured to move along the corresponding mounting rail to reposition the at least one retention bracket at a plurality of different mounting locations along the corresponding mounting rail based on a width of the post, and mount to the corresponding mounting rail.

11. The rail kit of claim 10, wherein each retention bracket comprises a slot extending along a longitudinal axis of the rail kit, and wherein the at least one retention bracket is configured to be mounted to the corresponding mounting bracket by inserting a fastener through the slot and mating the fastener with a hole formed in the corresponding mounting rail, and wherein the at least one retention bracket is configured to slide relative to the fastener to reposition the at least retention bracket along the corresponding mounting rail.

12. A system comprising:
a two-post rack;
a rail kit comprising:
a plurality of mounting rails, each comprising a first side, a second side opposite to the first side, and a track extending along the first side; and
a plurality of retention brackets, each mounted to the second side of a corresponding mounting rail of the plurality of mounting rails and to a post of the two-post rack; and
an information processing device comprising:
a chassis comprising a first peripheral side and a second peripheral side, each extending parallel to one another and along a longitudinal axis of the chassis;
a plurality of spools spaced apart from each other and extending perpendicularly from each of the first and second peripheral sides in a mutually opposite direction along a lateral axis of the chassis; and
a plurality of track-travelling discs including at least one disc mounted to one spool of the plurality of spools on the first peripheral side of the chassis and at least one disc mounted to one spool of the plurality of spools on the second peripheral side of the chassis, wherein the plurality of track-travelling discs engages with and travels along the tracks of the plurality of mounting rails to detachably mount the information processing device to the two-post rack through the rail kit.

13. The system of claim 12, wherein the plurality of spools arranged in the information processing device is configured to detachably mount the information processing device to the mounting rail installed in a four-post rack.

14. The system of claim 12, wherein the plurality of track-travelling discs mounted to the plurality of spools is configured to detachably mount the information processing device to the mounting rail installed in a two-post rack.

15. The system of claim 12, wherein each spool comprises a wider head portion and a narrower shaft portion extending from the wider head portion, and wherein each disc comprises an attachment member and a keyhole having a wider hole portion and a narrower hole portion extending from the wider hole portion.

16. The system of claim 15, further comprising a plurality of cantilever spring latches, each including a fixed end having a complementary attachment member and a free end having a locking tab, wherein the fixed end of each cantilever spring latch is coupled to the corresponding disc by engaging the attachment and complementary attachment members to one another such that the free end of the cantilever spring latch is movable between a latched state and an unlatched state to releasably secure the disc to a corresponding spool.

17. The system of claim 16, wherein, in the unlatched state of each cantilever spring latch, the locking tab of the cantilever spring latch is disengaged from the wider hole portion of the corresponding disc and the wider head portion of each spool is positioned in the wider hole portion of the corresponding disc so as to release the corresponding disc from the spool.

18. The system of claim 16, wherein, in the latched state of each cantilever spring latch, the locking tab of the cantilever spring latch is engaged with the wider hole portion of the corresponding disc and the narrower shaft portion of each spool is positioned in the narrower hole portion of the corresponding disc so as to hold the corresponding disc to the spool.

19. The system of claim 15, wherein each disc is configured to travel along the track by at least one of a sliding motion or a rolling motion relative to a narrower shaft portion of a corresponding spool.

20. The system of claim 12, wherein at least one retention bracket of the plurality of retention brackets is moved along the corresponding mounting rail to reposition the at least one retention bracket at a plurality of different mounting locations along the corresponding mounting rail based on a width of the post, and mount to the corresponding mounting rail.
